(19) United States
(12) Patent Application Publication
(10) Pub. No.: US 2015/0168259 A1
(43) Pub. Date: Jun. 18, 2015

(54) Systems and Method for Developing and Testing Hybrid Energy Storage Devices

(71) Applicant: MAN Truck & Bus AG, Muenchen (DE)

(72) Inventor: Markus HOFMANN, München (DE)

(21) Appl. No.: 14/568,888

(22) Filed: Dec. 12, 2014

(30) Foreign Application Priority Data
Dec. 13, 2013 (DE) 10 2013 021 004.6

(51) Int. Cl. G01M 15/04; G01R 31/34

(52) U.S. Cl. CPC G01M 15/044; G01R 31/34

(57) ABSTRACT

A system for developing, optimizing, and testing hybrid energy storage devices includes a test arrangement and a simulation device. The test arrangement has an emulator of a hybrid energy storage device connected to a driving operation emulator for receiving and outputting energy. The emulator includes a first energy storage device emulator, a second energy storage device emulator, and a power electronics unit controlling a supply of energy into the first and second energy storage device emulator and controlling a draw of energy from the first and second energy storage device emulator. The energy storage device emulators emulate different classes of energy storage devices and different operating states of an energy storage device by varying energy storage device parameters. A control device controls the power electronics unit. The simulation device simulates the operation of hybrid energy storage devices for different configurations of the control device and different energy storage device parameters.

### CROSS-REFERENCE TO RELATED APPLICATIONS

The present application claims priority of DE 10 2013 021 004.6, filed Dec. 13, 2013, the entire contents of which is incorporated herein by reference.

### BACKGROUND OF THE INVENTION

The invention relates to a system for developing, optimizing and/or testing hybrid energy storage devices. The invention further relates to a method for developing, optimizing and/or testing hybrid energy storage devices.

Hybrid energy storage systems are increasingly being used in motor vehicles. The term “hybrid energy storage device” is understood to mean the combination of at least two storage devices having preferably different characteristics. Hybrid energy storage systems have the advantage that the systems can be better designed and optimized for the different power requirements during the driving operation. By way of example, it is thus possible to combine in one hybrid energy storage device a storage device having a high energy density or rather storage capacity and a storage device having a high power density. The storage device having the high energy density or rather storage capacity renders possible a long range for an electrically driven vehicle, the storage device having the high power density is in contrast able to absorb for a short period of time high energy influences that occur by way of example in the case of a recuperation operation during braking.

In the case of developing hybrid energy storage systems of this type, there is the difficulty of optimally controlling and configuring the energy storage system by selecting suitable parameters for the different requirements during the driving operation.

The intelligence of a hybrid storage device lies in controlling the power electronics unit between the individual energy storage devices. A decision is made using a control device regarding from which of the energy storage devices energy that will be consumed by the driving operation is to be drawn and in which energy storage device the energy that is output by the driving operation is to be stored. The power electronics unit that controls the energy flows between the energy storage devices is then correspondingly controlled by the control device. An optimal process of controlling the power electronics unit can by way of example be any control process that renders possible the most energy efficient operation of the vehicle and/or any control process that keeps deterioration of the power capability of the energy storage device to a minimum over its serviceable life.

The configuration of the control device generally depends upon the energy storage devices that are used and their configuration and also on the requirements of the vehicle specific driving operation so that in the case of many vehicle variants it is necessary for the different variants in each case to determine an optimal configuration of the control process of the power electronics unit for the hybrid energy storage device system. Matters are complicated by the fact that the characteristics of an energy storage device typically change dynamically with its operating state. By way of example, the power capability of an energy storage device changes with its aging state that in turn depends on the number and type of charging and discharging processes that are in turn influenced by the driving operating requirements and on the configuration of the control process of the energy flows.

Approaches for investigating the control process of the power electronics unit and the influence on the energy storage device system for the purpose of developing hybrid energy storage device systems are known from the prior art, these approaches utilizing test drives with a test vehicle. However, approaches of this type require a large cost outlay and a considerable amount of time in order to test different configurations.

### SUMMARY OF THE INVENTION

An object of the invention is to avoid disadvantages of conventional approaches for developing and testing hybrid energy storage device systems. An object of the invention is in particular to provide a system and a method for developing, optimizing and testing hybrid energy storage device systems to determine as optimally as possible a configuration of a hybrid energy storage device in a rapid and cost-effective manner.

The object is achieved by a system having a test arrangement in which the energy consumption during a driving operation and/or a process of generating energy during the driving operation and also the behaviour of a hybrid energy storage device are simulated by emulators in such a manner that the energy storage devices can be tested with the power electronics unit and using real electric currents.

For this purpose, the test arrangement comprises a driving operation emulator that is designed so as to emulate a consumption of energy and/or a process of generating energy during the driving operation of a motor vehicle. By way of example, the driving operation emulator can be emulated with a controlled power electronics unit that is also described hereunder as a DC-source/sink that can be controlled according to a driving operation model in such a manner that the DC-source/sink receives energy flows or rather current corresponding to a consumption of energy during a driving operation and outputs energy flows or rather current corresponding to a process of generating energy during a driving operation. Alternatively, the driving operation emulator can also be formed by a “real” traction drive that is operated in conjunction with a dynamometer, by way of example on a test stand. The dynamometer is in this case designed in such a manner that it simulates typical loads during a driving operation and also can be operated in such a manner that processes for the purpose of generating energy by way of example recuperation processes can be represented.

The test arrangement further comprises an emulator of a hybrid energy storage device that is connected to the driving operation emulator for the purpose of receiving and/or outputting energy. The emulator of the hybrid energy storage device is consequently designed so as to output energy or rather current for the purpose of meeting the energy consumption requirement of the driving operation emulator and to receive energy or rather current that is generated by the driving operation emulator.

The emulator of a hybrid energy storage device comprises a first energy storage device emulator and at least one second energy storage device emulator for the purpose of simulating a hybrid energy storage system with at least two energy storage devices. Furthermore, a power electronics unit is provided to supply energy into the first and the at least second energy storage device emulator and by means of which it is possible to draw energy from the first and the second energy storage device emulator.

The first energy storage device emulator, the at least one second energy storage device emulator and the power electronics unit consequently simulate a hybrid energy storage device and can be operated and tested with real energy flows or rather currents.

A particular advantage of the invention further resides in the fact that the energy storage device emulators can be configured in each case by varying the energy storage device parameters of different classes of energy storage devices, in other words to emulate different types of energy storage devices and different operating states of an energy storage device.

The energy storage device parameters can comprise at least one of the following parameters of the energy storage device: the energy density, the power density, the storage capacity and/or the state of charge (SoC) of the energy storage device. As a result of varying these parameters it is possible to simulate different classes of energy storage devices and/or different operating states for example different aging states of a specific energy storage device of a class.

Furthermore, a control device is provided that is embodied so as to control the power electronics unit in such a manner that the control device indicates to the power electronics unit which of the energy storage device emulators is to provide energy for the driving operation emulator and/or which of the energy storage device emulators is to store the energy that is generated by the driving operation emulator. In this case, the control device can be likewise designed so as to implement different control methods, for example, by varying control parameters or generally the configuration of the control device.

The system further comprises a simulation device that is designed so as to simulate the operation of the test arrangement for different configurations of the control device and/or different energy storage device parameters.

A particular advantage of the invention consequently resides in the fact that as a result of using energy storage device emulators, the combination of different energy storage classes in one hybrid energy storage system and/or different operating states of energy storage devices can be simulated by suitable parameterization of the energy storage device emulators and can be tested with a simulation using actual currents in combination with the power electronics unit that is to be optimized and the control device. Furthermore, the driving operation emulator renders it possible to emulate different load requirements of the driving operation, by way of example different driving resistances and also different recuperation processes in a controlled test environment, in order to achieve comparable test results of the hybrid energy storage device. Furthermore, the test system renders it possible to test different control methods for the purpose of controlling the power electronics unit in that the control method that is built into the control device is varied for different test operations.

In accordance with a preferred exemplary embodiment, the first energy storage device emulator and/or the at least one second energy storage device emulator comprises a controllable DC-source/sink. Programmable voltage-current sources that can emulate a predefined voltage behaviour and current flows are known from the prior art. In accordance with an embodiment of the invention, the process of controlling the DC-source/sink is performed by a stored energy device storage model. The energy storage device model models the characteristics and the behaviour of a specific energy storage device. A control process controls the DC source/sink in real-time in dependence upon the energy storage model.

In other words, in the case of an energy storage device simulation of this type, a power electronics unit that forms a DC-source/sink is controlled by a real-time control process in such a manner that said power electronics unit thus behaves in a similar manner to a specific energy storage device in terms of voltage and current at its DC-terminals. For this purpose, the current and, where necessary, further values can be measured at the DC-terminals of the power electronics unit and can be used by the control device as input values for a stored energy storage device model of the allocated emulated energy storage device. A reaction of the emulated energy storage device to the measured emulated charging or discharging process can be provided to the controllable DC source/sink in the form of a desired value for the DC-terminal voltage in dependence upon the stored energy storage device model and the measured current value and, where necessary, further measurement values. In this manner, it is possible to emulate different storage types, in other words storage classes, and also different configurations of a specific storage device. The parameters of the emulated energy storage device can be consequently changed in a rapid and simple manner.

The controllable DC-source/-sink and the control process of the DC-source/sink with the stored energy storage device model can be integrated into a structural unit.

Within the scope of the invention, there is further the possibility of arranging the functionality of an energy storage device emulator in a distributed manner. In accordance with a further advantageous variant of the embodiment, a computer is provided in which the energy storage device model of the emulated energy storage device of the hybrid energy storage device are stored centrally and the computer is connected by way of signal lines in each case to the controllable DC-source/sinks.

The current value that is measured at the DC-terminal of the respective DC-source/sink is transferred to the computer by the signal lines as an input value for the stored respective energy storage device model. The computer then determines for each DC-source/sink, in dependence upon the respective energy storage model, the desired value for the DC-terminal voltage and indicates the desired value by the control line to the controllable DC-source/sink. This has the advantage that all the DC-sources/sinks can be controlled by one central computer. The computer is a real-time computer so that the energy flows can be emulated with real currents in real-time.

Furthermore, the computer can be simultaneously used in order to adjust the parameterization of the energy storage device emulators at a central position. In this exemplary embodiment, the central computer is consequently a part of the emulated hybrid storage device since the storage models are stored in the computer and the computer functions as a control process of the DC-source/sink.

In the above mentioned embodiment variant having a central computer in which in each case the energy storage model of the individual energy storage device emulators are stored, the computer can be further designed to operate as the above mentioned simulation device. The computer is consequently further designed so as to simulate the operation of hybrid energy storage devices by the test arrangement for different energy storage device parameters by varying energy storage device parameters in the stored energy storage device model. As a consequence, the emulation of the hybrid energy storage device and the parameterization and simulation of the entire system can be controlled from a central position.

In accordance with a further embodiment variant, a driving operation model is further stored in the central computer and is used for the purpose of controlling a power electronics unit of the driving operation emulator in order to indicate a consumption of energy by a driving operation that must be operated by the hybrid energy storage system or rather to indicate a process of generating energy by a driving operation, wherein the energy that is generated is received by the hybrid energy storage system.

In accordance with a preferred exemplary embodiment, the first energy storage device emulator is designed so as to emulate an energy storage device with a higher energy density and a lower power density than the second energy storage device emulator. As a consequence, a hybrid storage system of the conventional types can be simulated in order to be able both to store a high total energy amount as well as to be able to temporarily absorb or rather output high energy flows.

By way of example, the first energy storage device can emulate a chargeable battery and the at least one second energy storage device emulator can be designed so as to emulate a power storage device, preferably a super capacitor or double layer capacitor.

In accordance with a further aspect of the invention, the power electronics unit that regulates the energy flows between the energy storage device emulators can be arranged between the energy storage device emulator having the higher power density and a high voltage direct current power supply (HV-direct current power supply). The HV-direct current power supply is preferably configured as a conventional on-board power supply of vehicles having traction energy storage devices, in other words for example having a voltage in the magnitude of several hundred volts.

The test arrangement can further comprise an emulator of a further energy source. By way of example, the energy source can comprise a fuel cell, an internal combustion engine having a generator and/or an overhead contact line, for example an overhead contact line for buses that are supplied from the street. A particular advantage of the invention consequently resides in the fact that the integration of other energy sources is possible in the form of a simulation in order to also test the hybrid energy storage system for configurations in which an additional energy source is present.

It is emphasized that the present invention is not only possible for the purpose of developing, optimizing and/or testing hybrid energy storage devices but rather that the inventive idea can also be used in order to test and optimize user-defined arrangements of an energy storage device having at least one further energy source. In terms of this description, an energy source differs from an energy storage device in that an energy source, in contrast to the energy storage device, cannot receive energy flows for the purpose of storage.

In accordance with a modification to the above described system, the invention relates further to a system for developing and testing energy storage devices. The system comprises a test arrangement that comprises: a driving operation emulator that is designed so as to emulate an energy consumption and/or a process of generating energy during a driving operation of a motor vehicle; at least one energy source emulator that is designed so as to emulate energy generation of an energy source for a vehicle; an energy storage device emulator that is connected to the driving operation emulator and the at least one energy source for the purpose of receiving and/or outputting energy; and a power electronics unit by means of which the energy from the energy storage device emulator and the first energy source can be supplied to the driving operation emulator and by means of which the energy that is generated by the driving operation emulator and the at least one energy source can be supplied to the energy storage device emulator.

The energy storage device emulator and the at least one energy source can be designed in each case to vary parameters to emulate different classes of energy storage devices and/or energy sources and/or different operating states of an energy storage device and/or an energy source.

The test arrangement further comprises a control device that is embodied to control the power electronics unit such that the control unit indicates to the power electronics unit whether energy required by the driving operation emulator is to be provided by means of the energy storage device emulator and/or by means of the at least one energy source and/or whether energy that is generated by the driving operation emulator and/or by the at least one energy source is to be supplied to the energy storage device emulator.

The system further comprises a simulation device that is designed so as to simulate the operation of the test arrangement for different configurations of the control device and/or different parameterizations of the energy storage device emulator and/or the at least one energy source.

For the purpose of avoiding repetitions, the above mentioned aspects relating to the system comprising the hybrid energy storage device emulator are also to be regarded as disclosed and can be claimed for the modification of the system having only one energy storage device emulator.

The object of the invention is also achieved by a method for developing, optimizing and/or testing hybrid energy storage devices using a system as described above.

The method comprises the following steps: establishing a first configuration of the test arrangement by a first selection of the energy storage device parameters of the energy storage device emulators and/or the control parameters of the control device; and testing the hybrid energy storage device by operating the test arrangement of the first configuration, wherein a value of a desired function is determined. The first configuration can preferably be a basic configuration in which the operating parameters of the energy storage device or rather of the energy storage device emulators and the control parameters of the control device are established using typical values that represent a suitable start for the optimization process. However, the start value or start configuration can also be selected in a user defined manner.

A first value of a desired function is determined during the operation of the first test configuration. The desired function can be selected in dependence upon the aim of the optimization process. By way of example, the desired function can be a range of the driving operation that is to be maximized. It is preferred that the desired function is a multi-criteria desired function since a hybrid energy storage device system is often to be optimized to different requirements.

After testing the first configuration, a variation of the energy storage device parameters of the energy storage device emulators and/or a variation of the configuration of the control device is performed, for example, by varying parameters of the control device and/or the configuration of the power electronics unit in order to implement a repeat test of the hybrid energy storage device by operating the test arrangement in the changed configuration.

The variation of the parameters and implementation of the process of testing the test arrangement is performed until the desired function has achieved a desired value, by way of example an optimal value, or until a stop criteria by way of example a specific number of test cycles has been achieved.

In summary, the present invention renders it possible to rapidly and cost-effectively determine an optimized configuration of a hybrid energy system. By way of example, an optimized control of the power electronics unit can be determined by varying the control parameters of the control device. Furthermore, the arrangement can be optimized for example to a user defined battery parameter by varying the energy storage device parameters. By way of example, energy storage devices can thus be tested with operating parameters that are changed as a result of an aging process. Furthermore, it is possible to determine a desired requirement at the storage device parameter. Thus, a manufacturer of a control unit and power electronics unit can determine the configurations of the energy storage device system that are particularly advantageous for his control/power electronics unit and the manufacturer can provide those configurations to the energy storage device manufacturer.

### BRIEF DESCRIPTION OF THE DRAWING

Further details and advantages of the invention are described hereinunder with reference to the attached drawings. In the drawings:

FIG. 1 illustrates a schematic block diagram of a system for the purpose of developing and testing hybrid energy storage devices; and

FIG. 2 illustrates a flow chart of a method for developing and testing hybrid energy storage devices in accordance with an exemplary embodiment.

### DETAILED DESCRIPTION OF THE PREFERRED EMBODIMENTS

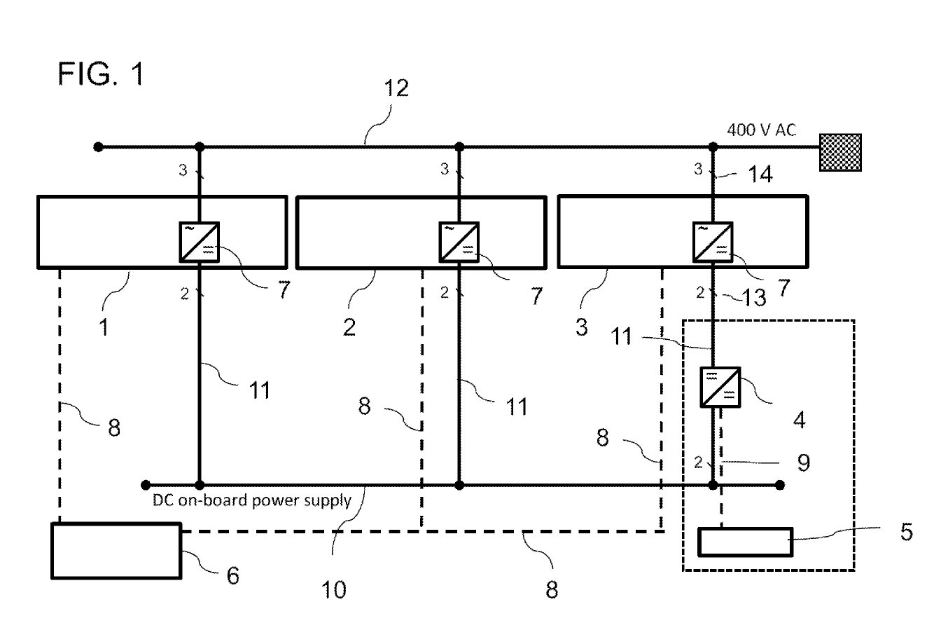

FIG. 1 illustrates in an exemplary manner an embodiment of a system with which it is possible to develop and test hybrid energy storage devices according to the invention.

In this case, a driving operation emulator 1 is provided with which the energy consumption and a process of generating energy during a driving operation of a motor vehicle is emulated. The driving operation emulator 1 is designed so as to emulate driving resistances or an energy consumption of auxiliary consumers, for example the air conditioning unit, and a process of generating energy during the driving operation for example by means of recuperation processes. The consumption of energy and/or the process of generating energy are illustrated by means of a controlled power electronics unit in the form of a DC-source/-sink 7.

For this purpose, a corresponding driving operation model is stored in a central real-time computer 6. During the operation of the test arrangement, the real-time computer 6 indicates desired values by way of a control line 8 of the DC-source/sink 7 for the process of generating or rather consuming energy so that the DC-source/sink 7 of the driving operation emulator generates corresponding current flows in the lines 11.

In the exemplary embodiment that is illustrated in FIG. 1, the real-time computer 6 with the stored driving operation model consequently forms a part of the functionality of the driving operating emulator 1. However, the possibility also exists of integrating the driving operation model and the allocated control process directly into one structural unit.

The test arrangement further comprises an emulator of a hybrid energy storage device that comprises a first energy storage device emulator 2 and a second energy storage device emulator 3 and also the power electronics unit 4. The hybrid energy storage device is connected to the driving operation emulator 1 for the purpose of receiving and/or outputting energy by way of the current lines 11.

The energy storage device emulator 2 comprises, in addition to the controllable DC-source/sink 7, an energy storage device model of the emulated first energy storage device that is stored in the real-time computer. The real-time computer 6 is also used as a control process in order to control the DC-source/sink 7 of the energy storage device emulator 2 in dependence upon the allocated energy storage device model by way of a signal line 8.

For this purpose, the current and where necessary further values are measured at the DC-terminal or DC-source/sink 7. The measured values are used as input values for the stored energy storage device model. The real-time computer 6 with the energy storage device model of the first energy storage device emulator 2 calculates from the input values the reaction of a real energy storage device to a measured charging and/or discharging process. The corresponding behaviour of the terminal voltage is then indicated as a desired value to the DC-source/sink 7. In this exemplary embodiment, a part of the functionality of the first energy storage device emulator 2, namely the energy storage device model and the control process, is consequently embodied centrally in the computer 6.

It has been previously mentioned that the functionality of the first energy storage device emulator 2 can be structurally integrated in one component.

The second energy storage device emulator 3 is embodied in a similar manner to the first energy storage device 2 having a controllable DC-source/sink 7. In the real-time computer 6, an energy storage device model of the second energy storage device emulator 3 is in turn stored so that, as described above for the first energy storage device emulator 2, the real-time computer 6 controls the DC-source/sink 7 so that the DC-source/sink 7 simulates the energy flows that the second energy storage device emulator 3 receives and/or outputs.

The emulators 1, 2 and 3 energize themselves from an alternating current power supply 12 that, in the present exemplary embodiment, is the conventional public AC power supply having 400 volts power supply voltage. The power supply 12 is used for the purpose of providing the energy or rather currents that are output by the emulators 1, 2 and 3 and for the purpose of receiving the energy flows or rather currents that are received by the emulators 1, 2 and 3 since the emulators themselves do not store energy.

The marking that is described with the reference numeral 14 describes the three-phase connectors of the AC power supply while the marking that is described with the reference numeral 13 connects the two-phase connectors (+/−) of the DC power supply.

The emulators 1, 2 and 3 are connected to the direct current power supply 10 that is operated with a typical voltage of an on-board power supply of hybrid vehicles or e-vehicles. Typical voltages of the direct current power supply 10 lie in the region of several hundred volts in order to be able to receive or rather provide the high powers in the driving operation.

The hybrid energy storage device further comprises a power electronics unit 4 that controls the energy flows between the two emulators 2 and 3. The power electronics unit 4 corresponds to a power electronics unit that is known from the prior art and is arranged for the purpose of controlling the energy flows between two hybrid storage devices. The power electronics unit 4 is therefore designed so as to supply energy to the first and second energy storage device emulator and to draw energy from the first and the second energy storage device emulator.

The power electronics unit 4 is controlled by a control device 5 that is connected by way of a control line 9 to the power electronics unit 4. As a consequence, the power electronics unit 4 can distribute to the energy storage device emulators the energy that is output or received by the simulated energy storage devices. The manner in which the energy flows are controlled is dependent upon additional input data at the control device 5. For example, the SoC (=state of charge) of the energy storage device emulators are a further input value. This can either be determined directly by the control device 5 by corresponding sensor technology (not illustrated) or can be sent via a data bus to the control device 5. A hybrid energy storage device can be optimized for different applications by means of controlling the energy flows.

The control device 5 indicates to the power electronics unit 4 in dependence upon the determined energy flows which of the energy storage device emulators 2, 3 is to provide energy for the driving operation emulator 1 and/or to which of the energy storage device emulators 2, 3 energy that is generated by the driving operation emulator 1 is to be supplied. For this purpose, the control device 5 sends control signals by way of the signal line 9 to the power electronics unit 4. The power switches are actuated in the power electronics unit 4 in dependence upon the control signals.

The arrangement of the power electronics unit 4 and the control unit 5 can also be embodied as one structural unit that is illustrated with the dashed line.

In the present example, a storage device having a high energy density, by way of example a battery, is emulated by the first energy storage device emulator 2, and an energy storage device having a high power density, by way of example a double layer capacitor, is emulated with the second energy storage device emulator 3.

The class of the energy storage device, by way of example whether a battery or a super capacitor is emulated, and the real configuration of a storage device, by way of example the real power and energy density, the charging state or the reaction time of the storage device are determined by establishing corresponding energy storage device parameters that are emulated as adjustable parameters in the energy storage model.

The described test arrangement can be tested for different parameterizations. For this purpose, a simulation device is provided that simulates the operation of the hybrid energy storage devices 2, 3 by the test arrangement for different control parameters and/or different energy storage device parameters. In the present example, the real-time computer 6 is in turn used as a simulation device.

The computer 6 indicates different parameter settings of the emulated energy storage device for different test cycles in order to monitor and evaluate for each parameter setting the behaviour of the energy storage device emulators 2, 3 in accordance with the control process by the control device 5 in reaction to an energy consumption and/or a process of generating energy of a driving operation that is emulated by the driving operation emulator 1.

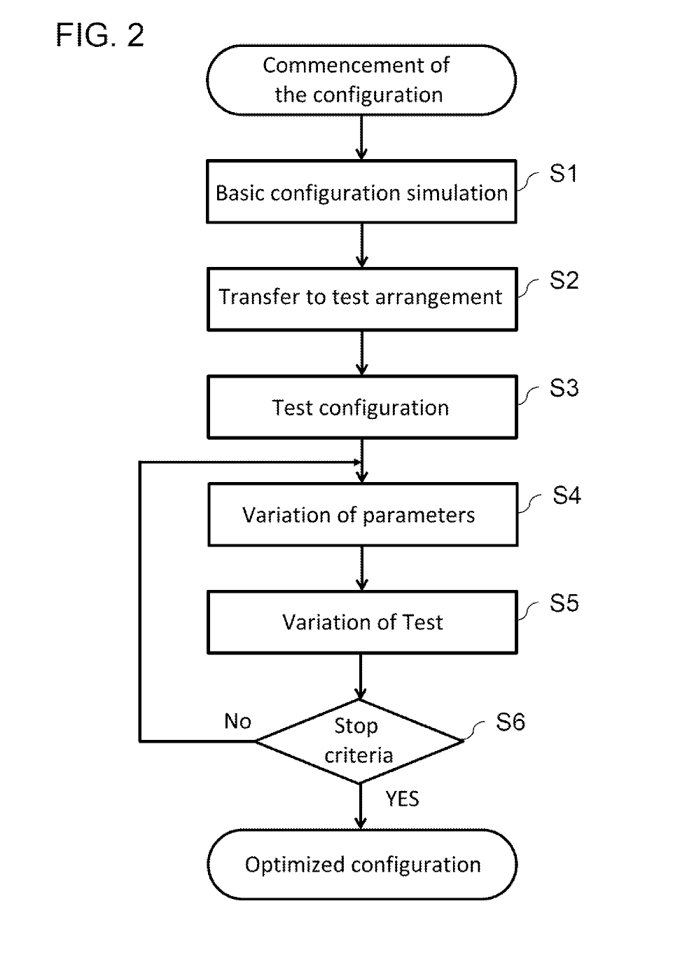

This is explained in an exemplary manner hereinunder with reference to FIG. 2.

In a first step S1, a basic configuration simulation is performed in which a first parameterization is performed. In this case, the energy storage device parameters are established in the energy storage device models in a first configuration.

By way of example, if an optimized control process 5 for a hybrid storage device having a battery and a double layer capacitor is to be tested, the energy storage device parameters, energy density and power density, for the first energy storage device emulator 2 are selected in such a manner that said energy storage device parameters emulate a battery having an indicated power and energy density and are selected for the emulator 3 in such a manner that said energy storage device parameter emulates a double layer capacitor having an indicated power and energy density.

A first control method for the process of controlling the power electronics unit 4 is selected for a basic configuration of the control device 5 in order to configure the control device 5 for a first operation. By way of example, a hitherto used control method can be used as a starting point.

In step S2, the selected parameterization of the energy storage device emulators 2, 3 and the control device 5 is transferred to the test arrangement. The energy storage model that is stored in the real-time computer 6 is parameterized with the parameters of the basic configuration and the control device 5 is designed so as to implement the selected control method.

Subsequently in step S3, a process of testing the configuration is performed. For this purpose, the real-time computer 6 starts the driving operation emulator 1 that emulates a driving operation and indicates a typical temporal cycle of the energy consumption and a process of generating energy of a motor vehicle. As a result of the energy flows that are generated by the driving operation emulator, the control device 5 indicates to the power electronics unit 4 in accordance with the stored control method which of the two energy storage device emulators 2, 3 is to be used to meet the energy requirement of the driving operation emulator 1. Furthermore, the control device 5 decides in the case of an energy input from the driving operation emulator 1 to which of the two DC-sources/sinks 7 of the energy storage device emulators 2, 3 the power electronics unit 4 is to supply the energy that is generated.

In accordance with the stored energy storage device model, the energy storage device emulators 2, 3 output current or receive current in dependence upon the control process by the power electronics unit 4.

During the test process, the simulation device, i.e., the real-time computer 6, determines different measurement data according to which the simulation device assesses the quality of the control process by the control unit 5, said measurement data being required for evaluation purposes for a predetermined desired function.

In step S5, a variation of the configuration of the test arrangement is subsequently performed. In this case, within the scope of the invention there is the possibility of changing both the parameterization of the energy storage device emulators 2, 3, for example in order to test the behaviour of the hybrid energy storage device in the case of different ageing states, as well as to design the control device 5 so as to implement different control methods. For each of the variations of the configuration of the test arrangement there then follows a repeat test in step S6, as described before in step S4 for the basic configuration.

The variation of the control parameters and the process of testing the modified control process of the power electronics unit can be repeated until an optimal configuration of the control process 5 has been determined, by way of example characterized by means of an optimal value of the desired function. Alternatively, a predefined stop criterion can also be provided in advance, by way of example a specific number of repetitions following which the step S5 and S6 are terminated and following which the results for the individual test operations can be evaluated with different configurations.

The test method in particular the steps S1 to S6 can also be implemented in a similar manner for the modified test arrangement having only one energy storage device emulator and at least one energy source.

Although the invention is described with reference to specific exemplary embodiments, a multiplicity of variants and modifications are possible that likewise make use of the inventive idea and therefore fall within the protective scope. Consequently, the invention is not to be limited to the disclosed specific exemplary embodiments, rather the invention is to comprise all exemplary embodiments that fall within the scope of the attached patent claims.

### LIST OF REFERENCE NUMERALS

1 Driving Operation Emulator
2 First Energy Storage Device Emulator
3 Second Energy Storage Device Emulator
4 Power Electronics Unit
5 Control Device
7 Controllable DC-source/sink
8, 9 Control Lines
10 DC Power Supply
11 Current Line
12 AC Power Supply
13 2-Phase Connectors DC Power Supply
14 3-Phase Connectors AC Power Supply

1. A system for developing and testing hybrid energy storage devices comprising:
a test arrangement; and
a simulation device,
wherein the test arrangement comprises:
a driving operation emulator configured to emulate at least one of an energy consumption and a process of energy generation during a driving operation of a motor vehicle;
a hybrid energy storage device emulator connected to the driving operation emulator for receiving energy produced by the process of energy generation and outputting energy for the energy consumption of the driving operation emulator, said hybrid energy storage device emulator comprising a first energy storage device emulator, a second energy storage device emulator, and a power electronics unit controlling a supply of energy into the first energy storage device emulator and the second energy storage device emulator and controlling a draw of energy from the first energy storage device emulator and the second energy storage device emulator, wherein each of the first energy storage device emulator and the second energy storage device emulator are configurable to emulate at least one of different classes of energy storage devices and different operating states of an energy storage device by varying energy storage device parameters; and
a control device configured to control the power electronics unit such that the control device indicates to the power electronics unit which of the first energy storage device emulator and the second energy storage device emulator is to provide energy for energy consumption of the driving operation emulator and which of the first energy storage device emulator and the second energy storage device emulator is to be supplied with energy that is generated by the process of energy generation of the driving operation emulator, wherein the control device is configurable to implement different control methods, and
wherein the simulation device simulates the operation of hybrid energy storage devices using the test arrangement for at least one of different configurations of the control device and different energy storage device parameters of the first energy storage device emulator and the second energy storage device emulator.

2. The system as claimed in claim 1, wherein the energy storage device parameters comprise at least one of the following parameters of the energy storage device: energy density, power density, storage capacity and state of charge (SoC).

3. The system according to claim 1, wherein the first energy storage device emulator and the second energy storage device emulator each comprise a controllable DC-source/sink, an energy storage device model and a control process, wherein the control process controls the DC-source/sink in dependence upon the energy storage device model.

4. The system according to claim 3, further comprising a computer in which the energy storage device models for the first energy storage device emulator and the second energy storage device emulator of the hybrid energy storage device are stored; and
signal lines connecting said computer to each of the DC-source/sinks of the first energy storage device emulator and the second energy storage device emulator,
wherein the computer is configured to determine by the signal lines a charging or discharging current value that is measured at a DC-terminal of each of the DC-source/sinks and to use the charging or discharging current as an input value for the stored energy storage device model of the emulated energy storage device, and the computer is further configured to simulate a reaction of the emulated energy storage device in the form of a desired value for the DC-terminal voltage at the controllable DC-source/sink in dependence upon the stored energy storage device model and the measured charging or discharging current value.

5. The system according to claim 4, wherein the computer is further is configured to be operated as the simulation device, wherein the operation of hybrid energy storage devices can be simulated by the test arrangement for different energy storage device parameters by varying energy storage device parameters in the stored energy storage device models.

6. The system according to claim 1, wherein the first energy storage device emulator emulates an energy storage device having a higher energy density and a lower power density than that of the second energy storage device emulator.

7. The system according to claim 6, wherein the first energy storage device emulator emulates a chargeable battery, and the second energy storage device emulator emulates a power storage device

8. The system according to claim 7, wherein the power storage device is one of a super capacitor or double layer capacitor.

9. The system according to claim 6, further comprising a direct current power supply operated with the voltage of the on-board power supply of the vehicle environment that is to be tested, wherein the power electronics unit is arranged between the second energy storage device emulator and the direct current power supply.

10. The system according to claim 1, wherein the driving operation emulator is emulated by a controlled power electronics unit or by a traction drive that is operated in conjunction with a dynamometer.

11. The system according to claim 1, wherein the test arrangement further comprises an emulator of an energy source.

12. The system according to claim 11, wherein the energy source comprises at least one of a fuel cell, an internal combustion engine having a generator, and an overhead contact line.

13. A system for developing and testing energy storage devices comprising:
a test arrangement; and
a simulation device,
wherein the test arrangement comprises:
a driving operation emulator configured to emulate at least one of an energy consumption and a process of energy generation during a driving operation of a motor vehicle;
at least one energy source emulator configured to emulate a process of generating energy of an energy source for a vehicle;
an energy storage device emulator connected to the driving operation emulator and to the at least one energy source for receiving energy and outputting energy; and
a power electronics unit controlling a supply of energy from the energy storage device emulator and the first energy source to the driving operation emulator and controlling a supply of energy that is generated by the driving operation emulator and the at least one energy source to the energy storage device emulator, wherein the energy storage device emulator and the at least one energy source are configurable to emulate different classes of energy storage devices or energy sources and different operating states of the energy storage devices and energy source by varying parameters; and
a control device configured to control the power electronics unit such that the control device indicates to the power electronics unit whether energy required by the driving operation emulator is provided by at least one of the energy storage device emulator and the at least one energy source and whether energy generated by the driving operating emulator and the at least one energy source is supplied to the energy storage device emulator;
wherein the simulation device simulates the operation of the test arrangement for at least one of different configurations of the control device, different parameters of the energy storage device emulator and the at least one energy source.

14. A method for developing and testing a hybrid energy storage device with a system having a test arrangement and a simulation device, the test arrangement having a driving operation emulator configured to emulate at least one of an energy consumption and a process of energy generation during a driving operation of a motor vehicle, at least one energy storage device emulator for receiving energy and outputting energy, a power electronics unit controlling a supply of energy to and from the at least one energy storage device emulator, and a control device controlling the power electronics unit, comprising the following steps:
establishing a first configuration of a test arrangement by selecting a first selection of energy storage device parameters of the at least one of energy storage device emulator and a first configuration of the control device,
testing the hybrid energy storage device by operating the test arrangement in the first configuration and determining a value of a desired function after the operation of the test arrangement in the first configuration, and
repeatedly establishing changed configurations of the test arrangement by varying at least one of the energy storage device parameters of the at least one energy storage device emulator and the configuration of the control device and repeatedly testing the changed configurations of the test arrangement until at least one of a value of the desired function achieves a predefined value and until a stop criteria is achieved.
